(19) United States
(12) Patent Application Publication
(10) Pub. No.: US 2009/0154113 A1
(43) Pub. Date: Jun. 18, 2009

(54) THERMAL ENERGY STORAGE FOR MOBILE COMPUTING THERMAL MANAGEMENT

(75) Inventor: Mark A. MacDonald, Beaverton, OR (US)

Correspondence Address: ALAN K. ALDOUS;Intel Corporation, c/o Intellevate, LLC, P.O. Box 52050, Minneapolis, MN, 55402, US

(73) Assignee: Inter Corporation

(21) Appl. No.: 11/954,678

(22) Filed: Dec. 12, 2007

(51) Int. Cl. H05K 7/20; H05K 3/00

(52) U.S. Cl. 361/720; 361/704; 29/829; 174/50

(57) ABSTRACT

In some embodiments, a device includes power source circuitry, a circuit board supporting electrical components to receive electrical power from the power source circuitry. The device further includes a housing forming a cavity including the circuit board, and thermal energy storage material held in the cavity, wherein the thermal energy storage material is distributed throughout various places in the cavity. Additional embodiments are described.

### BACKGROUND

1. Technical Field

Embodiments of the invention relate generally to using thermal energy storage material for temporarily storing thermal energy for mobile computing thermal management.

2. Background Art

Various thermal energy storage materials absorb substantial amounts of heat as their temperature increases across particular critical temperatures and conversely release the heat after the temperature decreases below those critical temperatures. Examples of such materials are phase change materials. Some phase change materials absorb heat in the process of melting (changing from a solid to a liquid phase) and then releasing heat as they solidify (changing from a liquid to a solid phase). For many thermal energy storage materials, heat absorption/desorption takes place nominally isothermally. This energy storage associated with the critical transition is in addition to other sensible energy stored by the material upon heating.

Such thermal energy storage materials have been used for a variety of purposes. Different materials have different characteristics such as the transition temperature, the heat capacity (which affects the speed at which they reach the transition temperature, subject to a given heat load), the amount of heat they may absorb/desorb at the transition temperature, thermal conductivity (which affects the maximum rate at which heat can be absorbed/desorbed from the material in a given geometry), and the mechanism through which energy is stored (e.g., physical or chemical). Uses of thermal energy storage materials include the following. Human organs have been transported by putting the organs in containers with materials that resist going above or below a particular temperature for an amount of time that is hopefully less than the time required for transportation. Phase change materials, such as paraffin wax, have been used in connection with heat sinks to temporarily absorb heat from electrical components that are temporarily in a high performance (turbo) mode of operation. Various materials, such as paraffin wax or hydrated salts, have been used in solar thermal energy collectors. Various materials, such as paraffin wax, hydrated salts, ice, or dry ice, have been used for storing temperature sensitive materials (e.g., food, chemicals, munitions). Various materials, such as paraffin wax or hydrated salts, have also been used in clothing for improving thermal comfort.

Examples of thermal energy storage materials that might be used to absorb heat and later release the heat include waxes (such as paraffin wax, octadecane, eicosane, etc.), vegetable extracts, polyethylene glycol, hydrated salts (such as Glauber's salt), fatty acids, esters, ionic liquids, and certain polymers. These and other materials may be mixed to achieve different properties. For example, paraffin can be mixed with graphite to achieve desired material properties. The materials include phase change materials and materials that under go chemical changes. Phase changes may include solid-liquid transitions, solid-gas transitions, liquid-gas transitions, solid-solid transitions, and liquid-liquid transitions—although some of these might not be practical for many circumstances. Some polymers and metals may have a change in crystal structure that is a solid-solid transition that may be considered a phase change. Chemical changes may include reversible chemical reactions (including solid-solid chemical transitions) and solution/dissolution changes. Trimethylolpropane (which may be a fine powder) is an example of a material that can undergo a reversible chemical reaction. Hydrated salt is an example of a material that may be viewed as undergoing either a phase change or a chemical change.

The heat produced by an electrical device including silicon integrated circuits (chips) is related to the number of transistors in operation and the voltage and frequency at which they operate. Typically, the heat at the surface (skin) of these devices is related to the performance of the chips, and other electrical components, and to any heat dissipation techniques. For example, laptop computers include fans to remove heat away from the laptop computer. Without the fan, the temperature at the skin of the laptop computer may become too hot to be comfortably handled.

Many handheld electrical devices such as cellphone devices and mobile internet devices, typically operate at a surface (skin) temperature such that they can be comfortably handled, even if they have been used for a long time. These devices do not include fans, but produce such a small amount of heat that fans are not needed. However, the computing capabilities of these devices is limited. For example, processors in these devices tend to have a relatively low throughput when compared to desktop or laptop mobile computers.

Efforts have been and are being made to provide computing devices (such as hand held devices) that have significantly greater computing capabilities than are provided by current cellphone devices and mobile internet devices. However, the higher computing capabilities will likely lead to greater heat and the possibility of the device surface (skin) temperature becoming uncomfortably hot. For example, for many people, a device skin temperature of around 45° C. is uncomfortable to hold. Because of the small sizes of the proposed devices, some current cooling techniques, such as including a fan, may not be practical or effective.

### BRIEF DESCRIPTION OF THE DRAWINGS

The invention will be understood more fully from the detailed description given below and from the accompanying drawings of embodiments of the invention which, however, should not be taken to limit the invention to the specific embodiments described, but are for explanation and understanding only.

FIG. 1 is a schematic cross-sectional representation of a housing including electrical components and thermal energy storage material in a solid state according to some embodiments of the invention.

FIG. 2 is a schematic cross-sectional representation of the housing and electrical components of FIG. 1 in which the thermal energy storage material is in a liquid state.

FIG. 3 is a perspective view of the housing of FIG. 1 according to some embodiments of the invention.

FIG. 4 is a graphical representation of skin temperature of a mobile device with and without a phase change material according to some embodiments of the invention.

FIG. 5 is a schematic cross-sectional representation of a mobile device including a housing including electrical components and into which thermal energy storage material may be placed according to some embodiments of the invention.

FIG. 6 is a schematic cross-sectional representation of the device of FIG. 5 from a different view.

FIG. 7 is a schematic cross-sectional representation of the device of FIG. 5 from a different view.

FIG. 8 illustrates sealing of portions of the housing of FIG. 5 according to some embodiments of the invention.

FIG. 9 is a schematic cross-sectional representation of a portion of the mobile device of FIG. 5 with a bag into which thermal energy storage material may be placed according to some embodiments of the invention.

FIG. 10 is a schematic representation of a display and keyboard that may be included in connection with the mobile device of FIG. 5 according to some embodiments of the invention.

FIG. 11 is a schematic representation of a mobile device similar to that of FIG. 5 with a flip display area according to some embodiments of the invention.

### DETAILED DESCRIPTION

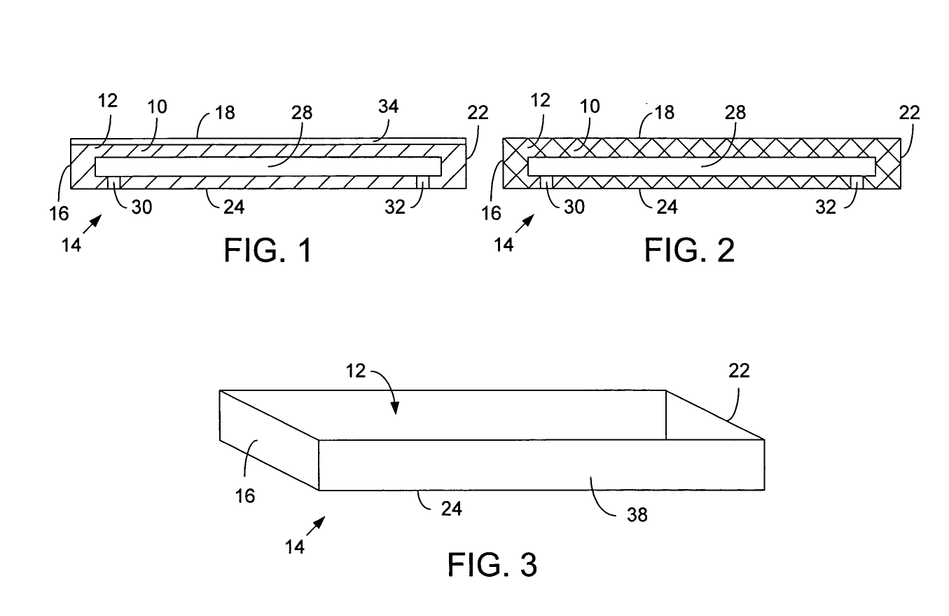

Referring to FIG. 1, thermal energy storage material 10 is provided to a cavity 12 of a housing 14 including sides 16, 18, 22, and 24. Electrical structures 28 (such as a printed circuit board (PCB) and integrated circuit chips) supported by stand posts including posts 30 and 32 are also included in the cavity. In the example of FIG. 1, thermal energy storage material 10 (represented by diagonal lines) is paraffin wax that is in a solid state and there is a slight air gap 34. Alternatively, in some implementations, there is not an air gap.

FIG. 2 is the same as FIG. 1 except that in FIG. 2 material 10 (represented by crossed lines) is in a liquid state after having absorbed energy from part of electrical structures 28 and has expanded in size so that air gap 34 is decreased. It may be desirable to include a flexible membrane that allows air to escape as the material expands, but not to allow the material to escape. The membrane, if used, could surround the material or merely be on one side. In some implementations, at least a portion of an air gap remains after the thermal energy storage material is in a solid state. If the amount of heat provided by electrical structures 28 is substantially reduced, the system temperature drops and material 10 re-solidifies.

FIG. 3 shows a perspective view of the housing of FIG. 1.

Examples of thermal energy storage materials that might be used to absorb heat and later release the heat include waxes (such as paraffin wax, octadecane, eicosane, etc.), vegetable extracts, polyethylene glycol, hydrated salts (such as Glauber's salt), fatty acids, esters, ionic liquids, and certain polymers. These and other materials may be mixed to achieve different properties. For example, paraffin can be mixed with graphite to achieve desired material properties. The materials include phase change materials and materials that under go chemical changes. Phase changes may include solid-liquid transitions, solid-gas transitions, liquid-gas transitions, solid-solid transitions, and liquid-liquid transitions—although some of these might not be practical for many circumstances. Some polymers and metals may have a change in crystal structure that is a solid-solid transition that may be considered a phase change. Chemical changes may include reversible chemical reactions (including solid-solid chemical transitions) and solution/dissolution changes. Trimethylolpropane (which may be a fine powder) is an example of a material that can undergo a reversible chemical reaction. Hydrated salt is an example of a material that may be viewed as undergoing either a phase change or a chemical change. In practice, some of these materials may not be suitable for electrical devices, but is expected that a paraffin based material will be useful in some implementations.

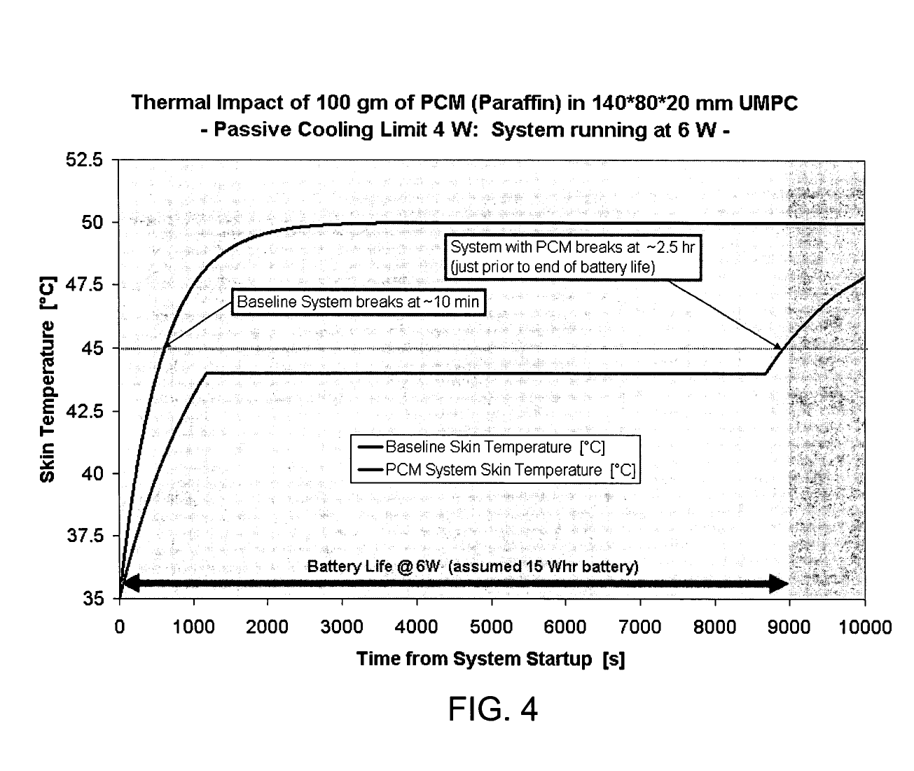

FIG. 4 is a graphical representation to illustrate differences that including thermal energy storage material in an electrical device can make. The values of the curves of FIG. 4 were obtained through calculations using various assumptions, but they are believed to be reasonably accurate, and they illustrate the principles even if they are not accurate in detail. An assumed baseline device is an ultra mobile personal computer (UMPC) device running at 6 watts (W) with a passive cooling limit based on natural convection and radiation of 4 W. The battery life at 6 W is assumed to be 9000 seconds (2.5 hours). The device has dimensions of 140*80*20 millimeters (mm) including unused space. The upper line shows skin (surface) temperature of the baseline system that does not include paraffin in the device. The skin temperature is the temperature in ° C. of a surface of the device, not the skin of the person holding the device. The time axis is in seconds. It is assumed that 45° C. is the maximum tolerable skin temperature (shown with a horizontal dotted line). Of course, an actual maximum tolerable skin temperature is different for different people. Note that the skin temperature of the baseline device reaches 45° C. at about 10 minutes.

The lower line shows skin temperature of the UMPC device when it holds about 100 gm of phase change material (PCM) (paraffin) in used space in the device. The paraffin absorbs heat from electrical components in the device until it reaches a transition temperature of the paraffin at about 44° C. at around 1000 seconds (16 minutes). While at the transition temperature, the paraffin continues to absorb heat while it melts. The paraffin stays at the transition temperature until it reaches the transition is complete, when essentially all the wax has melted at approximately 8700 seconds (145 minutes). It then increases in temperature, reaching the assumed maximum tolerable skin temperature of 45° C. at around 9000 seconds (2½ hours). This is compared to the 10 minutes of the baseline system. The temperature continues to rise until the heat source (such as from electrical components and perhaps also a battery) is reduced. For example, the heat source would be reduced if the battery runs out or the user turns off the device. The paraffin then gives off heat as its temperature is reduced and it eventually re-solidifies. Note that in FIG. 4, the battery runs out at 9000 seconds (2.5 hours) which is about the time 45° C. is reached. Once the batter runs out, the lower line would not continued to increase in temperature. The line is shown as increasing to illustrate what would happen if the device continued to operate. Further, the battery life may not always match the thermal absorbing properties of the material so neatly.

There may be particular hot spots in the device that are greater than the average temperature for the device. The designer may want to design the device such that the hot spots are at places that the user is less likely to touch or to put extra insulation or heat spreaders near hot spots to help avoid user discomfort.

Various factors may be considered in choosing a particular thermal energy storage material (including combinations of materials). These factors may include battery life, an expected length of time the user may choose to use the device, and an expected maximum temperature before the device is expected to be too hot for a user to touch. It may be that no material will meet all the desired criteria and the user will just stop using the device when it gets too hot for that user. However, through use of the invention, that length of time the device may be comfortably used will be significantly longer than without it.

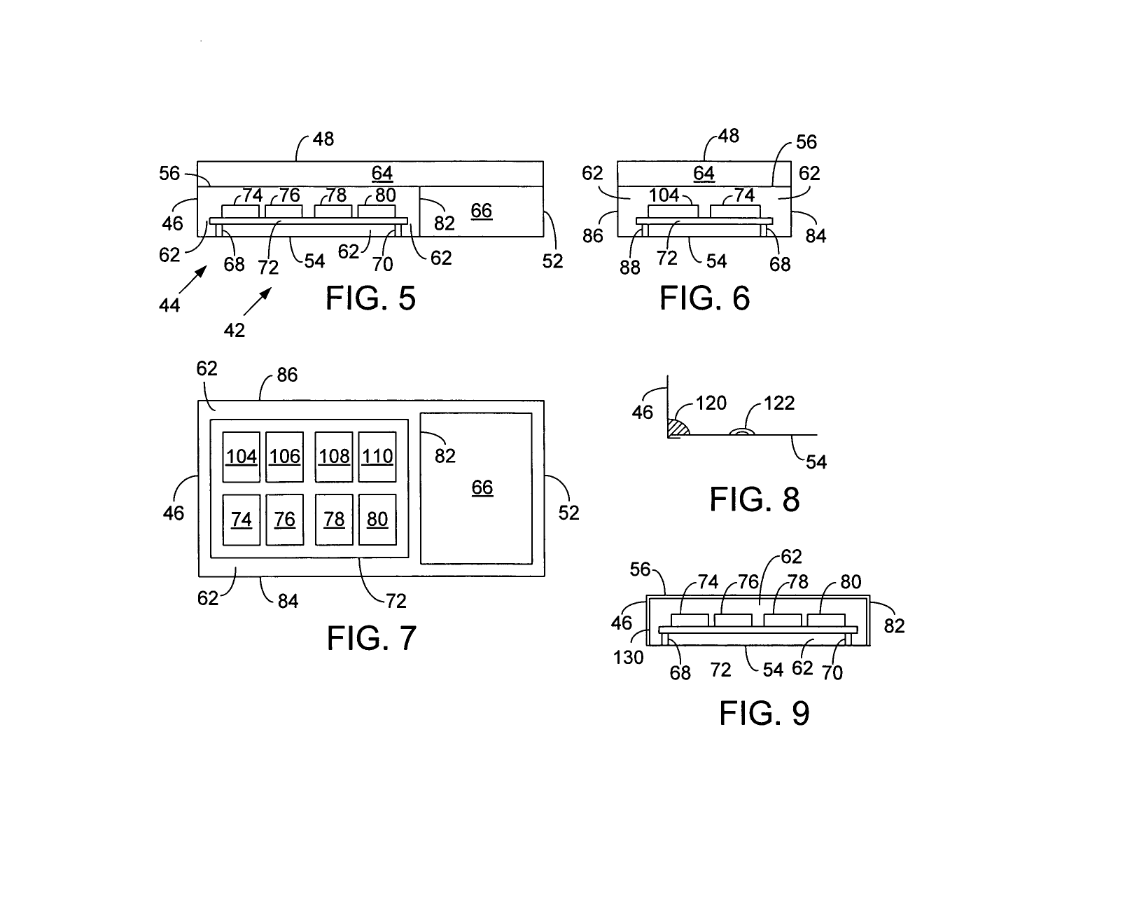

FIGS. 5, 6, and 7 show different views of an electrical computing device 42 having a body 44. Referring to FIG. 5, body 44 includes sides 46, 48, 52, and 54. A circuit board 72 supports electrical components 74, 76, 78, and 80 which may be integrated circuit chips, capacitors, and other devices. In actual practice, components 74, 76, 78, and 80 are not necessarily all the same size. Battery circuitry 66 may include one or more of various types of suitable batteries and associated conductors and is not restricted to any particular type of battery. A portion 62 may include a display and keyboard.

A side 56 along with sides 46, 52, 54, 82, 84, and 86 form a housing for a cavity 62. (Alternatively, side 82 may extend from side 84 to 86.) Thermal energy storage material (like material 10 in FIGS. 1 and 2) is in cavity 62. The material is not shown in diagonal or crossed lines to avoid clutter in FIGS. 5-9. Stands 68 and 70 support circuit board 72. FIG. 6 is viewed in the direction of the side 46 to side 82 of FIG. 5 and additionally shows sides 84 and 86, stand 88, and component 104. FIG. 7 is viewed from the direction of side 56 to side 54 of FIG. 5, and compared to FIG. 5 additionally shows sides 84 and 86 and components 104, 106, 108, and 110.

Thermal energy storage material may be distributed throughout cavity 62. For example, the material may go between circuit board 72 and side 54, and between components 74, 76, 78, and 80 and side 56. As shown in FIG. 7, cavity 62 may surround some portion of battery circuitry 66 so that material may go around battery circuitry 66. Alternatively, side 82 may extend completely to prevent this. It may be useful to put the material in cavity 62 in a liquid or powder form rather than in a solid form.

In some implementations, the amount of thermal energy storage material in cavity 62 may be more than 50% of the cavity volume. If the cavity volume is defined to not include structure such as the circuit board and electrical components, then the material may take up much more than 50% of the cavity, for example, 90% of the cavity, but this is not the case in other implementations.

There may be some holes in the device that allow material to leak out. To prevent leakage, a sealant may be applied. For example, FIG. 8 shows that sealant portion 120 applied to a corner where sides 46 and 54 meet to prevent leakage of material. A sealant portion 122 is provided to a hole in side 54. The sealant may be in globs or as a spay sealant used throughout. Alternatively, cavity 62 may be formed in a housing that does not have leaks and the material may be such that it does not leak. For example, in FIG. 9, cavity 62 is inside a bag 130. Circuit board 72, electrical components 74-80, stands 68 and 70, and the material is inside bag 130. The material stays inside of bag 130 such that it does not leak out of body 44. Bag 130 may allow substantial heat transfer such that the electrical components do not get too hot. In some implementations, a portion of bag 130 is pressed between the bottom of stands 68 and 70 and side 54. In some implementations, it does not matter if body 44 is not sealed or a bag is not used, because the material may be of a type that does not leak.

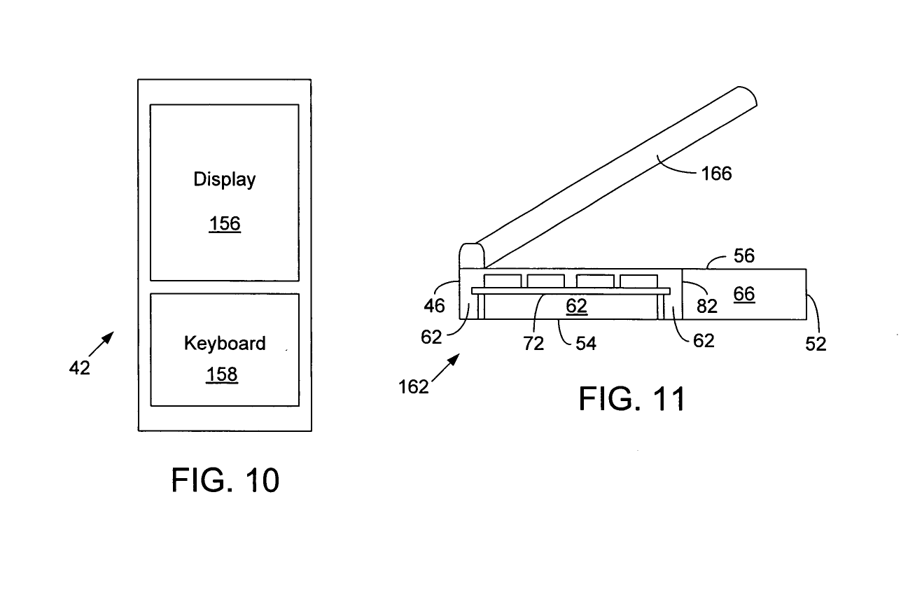

FIG. 10 illustrates a display 156 and a keyboard 158 that may be in portion 64 of FIG. 5. Alternatively, as shown in FIG. 11, the display may be in a section 166 of a device 162. A keyboard may be part of a display such as through a touch screen.

Devices 42 and 162 may be arranged in various other ways. For example, the battery may extend at the bottom of the device rather than be located as shown in FIG. 5. The sides may be more irregular in shape. The body of the devices may be formed in various ways including through snapping or other wise joining together molded plastic shells. The different sides can be different parts of one or more shells. In some implementations, there are gaps between sides such as sides 46, 84, and 86 and the outside surface of body 44. In some implementations, some or all of the electrical components are physically separated from the material. In some implementations, the device does not include a fan, but in some implementations it may include a fan.

Different examples of devices, such as devices 42 and 162, may be different sizes including hand held sizes. In some implementations, the device includes a body with length, width, and heigth dimensions of less than 20 centimeters by 13 centimeters by 4 centimeters. The devices may include length, width, and heigth dimensions of less than 15 centimeters by 10 centimeters by 2 centimeters. As noted, the bodies do not have to have straight lines and right angles.

There may be additional cavities in the device that may or may not hold additional thermal energy storage material. For example, portion 64 may include a cavity with thermal energy storage material.

### ADDITIONAL INFORMATION AND EMBODIMENTS

An embodiment is an implementation or example of the invention. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments.

When it is said the element “A” is coupled to element “B,” element A may be directly coupled to element B or be indirectly coupled through, for example, element C.

When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.” Likewise, that A is responsive to B, does not mean it is not also responsive to C.

If the specification states a component, feature, structure, process, or characteristic “may”, “might”, or “could” be included, that particular component, feature, structure, process, or characteristic is not required to be included. If the specification or claim refers to “a” or “an” element, that does not mean there is only one of the element.

The invention are not restricted to the particular details described herein. Indeed, many other variations of the foregoing description and drawings may be made within the scope of the present invention. Accordingly, it is the following claims including any amendments thereto that define the scope of the invention.

What is claimed is:

1. A device comprising:
power source circuitry;
a circuit board supporting electrical components to receive electrical power from the power source circuitry;
a housing forming a cavity including the circuit board; and
thermal energy storage material held in the cavity, wherein the thermal energy storage material is distributed throughout various places in the cavity.

2. The device of claim 1, wherein the thermal energy storage material is in physical contact with at least some of the electrical components.

3. The device of claim 1, further comprising a bag placed inside the cavity, wherein the bag holds at least some of the thermal energy storage material.

4. The device of claim 1, wherein the thermal energy storage material is distributed throughout virtually all of the cavity that does not include structure such as the circuit board and the electrical components.

5. The device of claim 1, wherein the thermal energy storage material is of a sufficient amount to prevent a temperature at a surface of housing from reaching a particular temperature during an amount of time that a user is expected to use the device.

6. The device of claim 1, wherein the thermal energy storage material is of a sufficient amount to prevent a temperature at a surface of housing from reaching an uncomfortable level during an expected battery usage time.

7. The device of claim 1, wherein the thermal energy storage material includes paraffin wax.

8. The device of claim 1, wherein the housing includes various sides including first and second sides and the circuit board includes first and second sides, and the thermal energy storage material is included between the first side of the circuit board and the first side of the housing and between the second side of the circuit board and the second side of the housing.

9. The device of claim 1, wherein the thermal energy storage material takes up more than 50% of the cavity volume.

10. The device of claim 1, wherein the more than 90% cavity is filled with the thermal energy storage material that does not include structure such as the circuit board and the electrical components.

11. The device of claim 1, further comprising at least one additional cavity that includes additional thermal energy storage material.

12. The device of claim 1, further comprising a display responsive to signals from at least one of the electrical components.

13. The device of claim 1, further comprising a device body that supports the circuit board and power source circuitry and wherein the housing is within the device body, and wherein the device body is of a hand held size.

14. A device comprising:
a body including a housing forming a cavity;
a circuit board supporting electrical components to perform functions including computing functions, wherein at least part of the circuit board is included in the cavity; and
thermal energy storage material held in the cavity, wherein the thermal energy storage material is included in various places in the cavity.

15. The device of claim 14, wherein the body has length, width, and heigth dimensions of less than 20 centimeters by 13 centimeters by 4 centimeters.

16. The device of claim 14, wherein the body has length, width, and height dimensions of less than 15 centimeters by 10 centimeters by 2 centimeters.

17. The device of claim 14, further comprising a display responsive to signals from at least one of the electrical components.

18. A method comprising:
heating thermal energy storage material to cause a thermal energy storage material to be in a liquid phase; and
pouring the thermal energy storage material in a cavity formed by a housing of an electrical device such that it at least partially surrounds electrical components in the cavity.

19. The method of claim 18, further comprising placing a bag inside the cavity and wherein the thermal energy storage material is poured into the bag.

20. The method of claim 18 wherein the thermal energy storage material is distributed throughout virtually all of the cavity that does not include structure such as the circuit board and the electrical components.
